(19) United States
(12) Patent Application Publication
(10) Pub. No.: US 2026/0150512 A1
(43) Pub. Date: May 28, 2026

(54) DISPLAY DEVICE

(71) Applicant: LG DISPLAY CO., LTD., SEOUL (KR)

(72) Inventors: Dongyul Kim, Goyang-si (KR); ChangHeon Kang, Paju-si (KR); Jonghyun Han, Goyang-si (KR); Seongwoong Jeong, Paju-si (KR)

(21) Appl. No.: 19/345,099

(22) Filed: Sep. 30, 2025

(30) Foreign Application Priority Data
Nov. 28, 2024 (KR) 10-2024-0174087

(51) Int. Cl. H10K 59/122; H10K 59/80; H10K 59/88

(52) U.S. Cl. CPC H10K 59/122; H10K 59/8792; H10K 59/88

(57) ABSTRACT

A display device includes a substrate with sub pixels and dummy pixels; an anode disposed on the substrate to correspond to each of the sub pixels; a dummy anode disposed on the substrate to correspond to each of the dummy pixels; an auxiliary electrode disposed below the dummy anode and electrically connected to the dummy anode; a bank which covers an edge of the anode to define an open area above the anode; a cathode disposed on the anode and on the dummy anode; an encapsulation layer on the cathode; a plurality of color filters disposed on the encapsulation layer and corresponding to the sub pixels and the dummy pixels; and a black matrix interposed between adjacent color filters of the plurality of color filters.

### CROSS-REFERENCE TO RELATED APPLICATIONS

Pursuant to 35 U.S.C. § 119(a), this application claims the benefit of an earlier filing date and right of priority to Korean Patent Application No. 10-2024-0174087 filed on Nov. 28, 2024, in the Korean Intellectual Property Office, the disclosure of which is incorporated herein by reference in its entirety.

### TECHNICAL FIELD

The present disclosure relates to a display device.

### BACKGROUND

In the information era, there has been rapid development of display technology to visually express electrical information signals. Various display devices have been developed with excellent performance such as reduced thickness, light weight, and low power consumption. Examples of such display devices include a liquid crystal display device (LCD), a plasma display panel device (PDP), a field emission display device (FED), and an organic light emitting display device (OLED).

Among these, the organic light emitting display device is a self-emitting display device in which a separate light source is not necessary, which is different from the liquid crystal display device. As such, the organic light emitting display device can be manufactured to have light weight and reduced thickness. Further, the organic light emitting display device can be driven at a low voltage, providing advantages not only in terms of low power consumption, but also in faster response speed, better viewing angle, and improved contrast ratio, so that organic light emitting display devices are actively studied as next generation displays.

### SUMMARY

According to an aspect of the present disclosure, a display device includes a substrate in which a plurality of sub pixels and a plurality of dummy pixels are defined; an anode which is disposed on the substrate and is disposed so as to correspond to each of the plurality of sub pixels; a dummy anode which is disposed on the substrate and is disposed so as to correspond to each of the plurality of dummy pixels; an auxiliary electrode which is disposed below the dummy anode and is electrically connected to the dummy anode; a bank which covers an edge of the anode to define an open area above the anode; a cathode disposed on the anode and the dummy anode; an encapsulation layer on the cathode; a plurality of color filters which is disposed on the encapsulation layer and corresponds to the plurality of sub pixels and the plurality of dummy pixels; and a black matrix interposed between adjacent color filters of the plurality of color filters.

According to another aspect of the present disclosure, a display device includes: a substrate in which a display area and a non-display area outside a periphery of the display area are defined; a common voltage line which is disposed in the non-display area and applies a common voltage to the display area; an auxiliary electrode which is disposed across the display area and is electrically connected to the common voltage line; a first sub pixel including a first light emitting diode including a first anode and a first pixel circuit connected to the first light emitting diode; a second sub pixel including a second light emitting diode including a second anode and a second pixel circuit connected to the second light emitting diode; a third sub pixel including a third light emitting diode including a third anode and a third pixel circuit connected to the third light emitting diode; a dummy pixel including a dummy anode connected to the auxiliary electrode; and an anti-reflection layer including a first color filter overlapping the first anode, a second color filter overlapping the second anode, a third color filter overlapping the third anode, and a fourth color filter overlapping the dummy anode.

Other detailed matters of the example implementations are included in the detailed description and the drawings.

Such features can provide various technical effects. For example, according to some implementations of the present disclosure, in the display device, an auxiliary electrode and a cathode are in contact with each other and can help mitigate the luminance irregularity which may be caused by the voltage drop and improve the resolution of the display device.

According to some implementations of the present disclosure, in the display device, the external light reflection can be suppressed and the reflective luminosity can be improved.

According to some implementations of the present disclosure, the thickness of the display device can be reduced.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of an example of a display device according to an implementation of the present disclosure;

FIG. 2 is a schematic enlarged plan view of an example of an area A of FIG. 1;

FIG. 3 is a schematic cross-sectional view of an example of II-II′ of FIG. 2;

FIG. 4 is a schematic cross-sectional view of an example of a display device according to another implementation of the present disclosure; and

FIG. 5 is a schematic cross-sectional view of an example of a display device according to another implementation of the present disclosure.

### DETAILED DESCRIPTION

Implementations of the present disclosure can provide a display device which suppresses voltage drop of the display device and has an improved luminance uniformity, and improves a reflective luminosity when the display device is not driven.

In general, a top-emission type organic light emitting display device uses a transparent electrode or a transflective electrode, as a cathode, to emit light emitted from an organic emission layer to an upper portion of the organic light emitting display device. In order to acquire sufficient light transmittance to pass through the cathode, the cathode can should be formed with a very thin thickness. Accordingly, the cathode is often formed of an alloy of silver (Ag) and magnesium (Mg) or a transparent conductive oxide TCO with a sufficiently thin thickness. However, the thickness reduction of the cathode increases an electric resistance of a cathode electrode. In such scenarios, for an organic light emitting display device with a large area, display regions that are further away from a Vss voltage supply pad unit, which applies a voltage Vss to the cathode, can suffer a more severe voltage drop. This can result in a luminance irregularity problem of the organic light emitting display device. In the voltage drop phenomenon, there is a reduction of potential difference formed in a light emitting diode, and specifically, a reduction of a potential difference between an anode and a cathode of the light emitting diode.

A cathode of the organic light emitting display device is often formed using a metal material having a high reflectance. In such scenarios, external light is reflected by the metal material, which can result in a problem where the reflective luminosity and a contrast ratio are degraded. Therefore, in order to reduce the reflection by the external light, a polarization plate is disposed below a cover member to absorb the external light. The polarization plate is a film having a predetermined level of light transmittance and absorbs external light and reflected light thereof to suppress the degradation of the contrast ratio.

However, a polarization film can be costly to implement, and there is an increasing need for a display device that can achieve low reflectance, can increase light efficiency, and can implement a neutral black (reddish neutral black), without a polarization film. The term neutral black may refer to a color of a display device in a power-off state.

Further, there has been increased attention towards a flexible display device as a next generation display device. A flexible display device is manufactured to be capable of displaying images even though the flexible display device is bent or folded like paper. The flexible display device may be classified into an unbreakable display device having a high durability, a bendable display device which is bent without being broken, a rollable display device which is rolled, and a foldable display device which is folded. Such a flexible display device has advantages in terms of space utilization, interior, and designs and may have various application fields. In such a flexible display device, a structure in which a thin coated polarization film is applied instead of a thick polarization plate has been suggested. However, there are problems in that the thickness of the coated polarization film is also large and if the thickness is reduced, a function and a display quality of the polarization film are degraded.

Therefore, instead of the polarization plate or the coated polarization film, a color filter on encapsulation layer (CoE) structure has been utilized in some scenarios. The CoE structure is a structure in which the black matrix is disposed on the encapsulation layer so as to correspond to the non-emission area and the color filter is disposed so as to correspond to the emission area. According to the CoE structure, the thickness of the display device can be reduced and the transmittance is easily controlled so that external light and the reflected light are absorbed without degrading the luminous efficiency to improve the display quality. However, in the display device, an emission area is implemented to be different due to the difference in the lifespan of the light emitting diode disposed in each sub pixel. Therefore, in the CoE structure, there is a problem in which the reflection color stands out as a specific color due to the difference in the size of the opening of the black matrix corresponding to each sub-pixel.

Implementations of the present disclosure can help address one or more of the above-described problems by providing a display device which can improve the luminance uniformity and achieve a high resolution by suppressing the voltage drop.

Implementations of the present disclosure can provide a display device with a small thickness which suppresses external light reflection and has excellent reflective luminosity.

Objects of the present disclosure are not limited to the above-mentioned objects, and other objects, which are not mentioned above, can be clearly understood by those skilled in the art from the following descriptions.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, a display device according to example implementations of the present disclosure will be described in detail with reference to accompanying drawings.

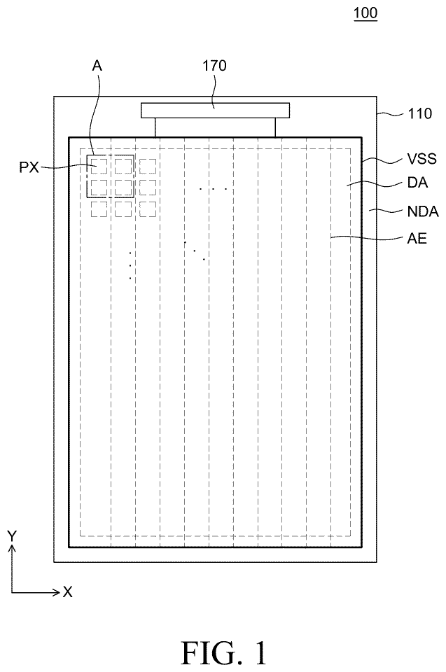

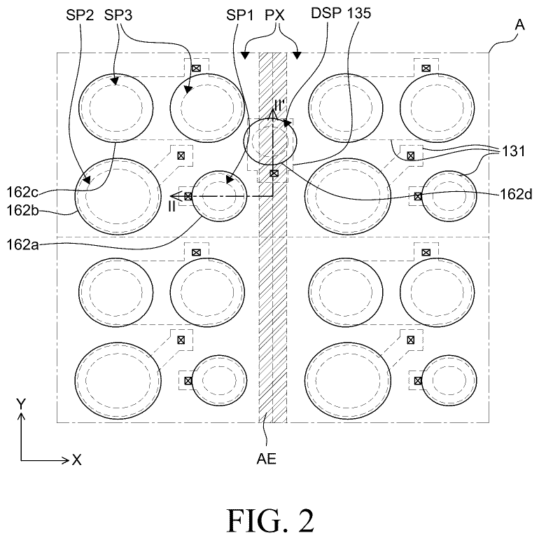

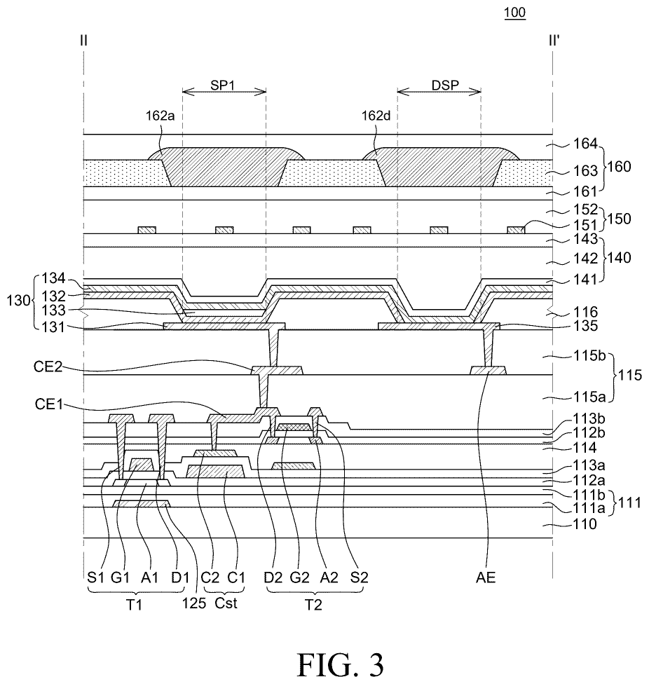

FIGS. 1 to 3 are schematic views of an example of a display device according to an implementation of the present disclosure. FIG. 1 is a schematic plan view of an example of a display device according to an implementation of the present disclosure. FIG. 2 is a schematic enlarged plan view of an example of an area A of FIG. 1. FIG. 3 is a schematic cross-sectional view of an example of II-II′ of FIG. 2.

Referring to FIGS. 1 to 3, a display device 100 according to the implementation of the present disclosure includes a substrate 110, thin film transistors T1 and T2, a capacitor Cst, a light emitting diode 130, an encapsulation layer 140, a touch sensor structure 150, an anti-reflection layer 160, a circuit unit 170, a common voltage line VSS, and an auxiliary electrode AE. Hereinafter, for the convenience of description, the display device 100 according to the example implementation of the present disclosure is assumed as an organic light emitting display device, but it is not limited thereto.

Referring to FIG. 1, the display device 100 according to the implementation of the present disclosure includes a display area DA and a non-display area NDA. The display area DA is an area where a plurality of pixels PX is disposed to substantially display images. In the display area DA, pixels PX including an emission area for displaying images and a driving circuit for driving the pixels PX may be disposed. The non-display area NDA may fully or partially surround the display area DA. The non-display area NDA may be an area adjacent to the display area DA. For example, the non-display area NDA is located outside a periphery of the display area DA. Further, the non-display area NDA may be an area disposed adjacent to the display area DA and configured to surround the display area DA. However, the present disclosure is not limited thereto. For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction.

The non-display area NDA is an area where images are not substantially displayed and various wiring lines, driving ICs, and printed circuit boards for driving the pixels PX disposed in the display area DA and the driving circuits are disposed. For example, in the non-display area NDA, various ICs such as a gate driver IC and a data driver IC may be disposed. In the meantime, as described above, in the non-display area NDA, the driving IC and the printed circuit board may be disposed and a predetermined area is necessary to dispose the driving IC and the printed circuit board.

The plurality of pixels PX is disposed in a matrix and each of the plurality of pixels PX includes a plurality of sub pixels. The plurality of pixels PX and the plurality of sub pixels will be described below with reference to FIG. 2.

Referring to FIG. 1, in the non-display area NDA, a common voltage line VSS which applies a common voltage to the display area DA is formed. The common voltage line VSS is disposed so as to enclose the display area DA, but is not limited thereto. The common voltage line VSS is connected to a cathode formed in the display area DA.

A plurality of auxiliary electrodes AE is disposed across the display area DA. The auxiliary electrode AE extends to the non-display area NDA to be electrically connected to the common voltage line VSS. The auxiliary electrode AE is connected to the cathode in the display area DA to apply a uniform common voltage to the entire display area DA, which can have a large area. By doing this, the voltage drop in different regions of the display device may be suppressed. A structure of the auxiliary electrode AE will be described below with reference to FIGS. 2 and 3.

Referring to FIG. 2, each of a plurality of pixels PX includes a plurality of sub pixels SP1, SP2, and SP3. Each sub pixel SP1, SP2, SP3 is an element which displays one color and includes an emission area where light is emitted and a non-emission area where light is not emitted, but in the present disclosure, only the emission area where the light is emitted is defined as a sub pixel. For example, each of the plurality of sub pixels SP1, SP2, and SP3 may display any one color of red, green, and blue, but is not limited thereto.

Referring to FIG. 2, one pixel PX may include a first sub pixel SP1, a second sub pixel SP2, and a third sub pixel SP3. For example, the first sub pixel SP1 and the second sub pixel SP2 may be disposed in a first direction (an X-axis direction) and the third sub pixel SP3 may be disposed along the first direction to be spaced apart from the first sub pixel SP1 and the second sub pixel SP2 in a second direction (a Y-axis direction). However, the present disclosure is not limited thereto. The first sub pixel SP1, the second sub pixel SP2, and the third sub pixel SP3 may display different colors and some sub pixels may display the same color as needed. In the meantime, any one of the first sub pixels SP1, the second sub pixels SP2, and the third sub pixels SP3 may be two or more. For example, one pixel PX may include one first sub pixel SP1, one second sub pixel SP2, and two third sub pixels SP3.

Each of the first sub pixel SP1, the second sub pixel SP2, and the third sub pixel SP3 may be any one of a red sub pixel, a green sub pixel, and a blue sub pixel. For example, the first sub pixel SP1 may be a red sub pixel, the second sub pixel SP2 may be a green sub pixel, and the third sub pixel SP3 may be a blue sub pixel. Hereinafter, the display device 100 according to the example implementation of the present disclosure will be described under the assumption that the first sub pixel SP1 is a red sub pixel, the second sub pixel SP2 is a green sub pixel, and the third sub pixel SP3 is a blue sub pixel. However, colors of the sub pixels are described as an example for the convenience of description so that the present disclosure is not limited thereto.

Further, in FIG. 2, it is illustrated that the plurality of sub pixels SP1, SP2, and SP3 has a circular shape, but it is not limited thereto and the shape of the sub pixels may be implemented in various shapes. For example, each sub pixel SP1, SP2, SP3 may have a polygonal shape other than a circular shape, an oval shape, or an octagonal shape.

In the meantime, referring to FIG. 2, a dummy pixel DSP is disposed between two pixels PX. In FIG. 2, the dummy pixel DSP is disposed in a boundary between two adjacent pixels PX to overlap a part of two pixels PX, but may also be disposed to be included in one pixel PX. For example, some pixels PX of the plurality of pixels PX may include a first sub pixel SP1, a second sub pixel SP2, a third sub pixel SP3, and a dummy pixel DSP. In some implementations, the dummy pixel DSP may be disposed so as to overlap or be adjacent to the auxiliary electrode AE.

Unlike each sub pixel SP1, SP2, SP3 each of which can emit a color, the dummy pixel DSP does not emit light. The dummy pixel DSP as described above improves the reflective luminosity and adjusts the reflective luminosity when the display device 100 is not driven.

Hereinafter, a specific configuration of the plurality of sub pixels and the dummy pixel will be described with reference to FIG. 3.

In FIG. 3, examples of cross-sections of the first sub pixel SP1 and the dummy pixel DSP are illustrated. In FIG. 3, a first sub pixel SP1, among the plurality of sub pixels SP1, SP2, and SP3 disposed in the display area DA, is illustrated as an example. However, the entire structures of the second sub pixel SP2 and the third sub pixel SP3 which represent different colors may be the same, except for light output from an emission stack which configures the light emitting diode 130.

Referring to FIG. 3, in one sub pixel, e.g., in the first sub pixel SP1, the plurality of thin film transistors T1 and T2 may be disposed above the substrate 110, and the planarization layer 115 may be disposed above the thin film transistors T1 and T2. The light emitting diode 130 may be disposed above the planarization layer 115, the encapsulation layer 140 may be disposed above the light emitting diode 130, and the touch sensing structure 150 and the anti-reflection layer 160 may be disposed above the encapsulation layer 140.

Further, in the dummy pixel DSP, the auxiliary electrode AE and the planarization layer 115 are disposed above the substrate 110 and a dummy anode 135, a common layer 132, and the cathode 134 are disposed above the planarization layer 115. As disposed in the first sub pixel SP1, the encapsulation layer 140 may be disposed above the cathode 134 and the touch sensing structure 150 and the anti-reflection layer 160 may be disposed above the encapsulation layer 140.

The substrate 110 is a base member for supporting various components included in the display device 100 and may be formed of an insulating material. For example, the substrate 110 may be a glass substrate or a plastic substrate. For example, the plastic substrate may be selected from polyimide, polyethersulfone, polyethylene terephthalate, and polycarbonate, but is not limited thereto. In order to implement a flexibility and a foldability, when a plastic substrate having a flexibility is used, a support member such as a back plate may be disposed below the substrate 110. The plastic substrate having flexibility is thinner and has a weaker rigidity than the glass substrate so that when various elements are disposed, the plastic substrate may be sagged. The back plate supports the substrate 110 formed of a plastic material so as not to be sagged and protects the display device 100 from moisture, heat, and impacts.

The first buffer layer 111 may be disposed on the substrate 110. For example, the first buffer layer 111 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto. Specifically, a multi-buffer layer 111a may be disposed on the substrate 110 and an active buffer layer 111b may be disposed on the multi-buffer layer 111a.

The metal layer 125 may be disposed between the substrate 110 and the multi-buffer layer 111a. Here, the metal layer 125 may serve as a light shield and may also be referred to as a light shielding layer.

The multi-buffer layer 111a may be disposed on the metal layer 125 and the active buffer layer 111b may be disposed on the multi-buffer layer 111a.

The plurality of thin film transistors T1 and T2 is disposed on the first buffer layer 111. The plurality of thin film transistors T1 and T2 is disposed in each of the first sub pixel SP1, the second sub pixel SP2, and the third sub pixel SP3.

The active layer of thin film transistor may be formed of a semiconductor material such as an oxide semiconductor, amorphous silicon, or polysilicon, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto. The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto. The amorphous semiconductor material may be made of amorphous silicon (a-Si), but is not limited thereto.

The first thin film transistor T1 may be disposed on the first buffer layer 111. The first thin film transistor T1 may include a first active layer A1, a first gate electrode G1, a first source electrode S1, and a first drain electrode D1. Here, depending on the design of the pixel circuit, the first source electrode S1 may serve as a first drain electrode and the first drain electrode D1 may serve as a first source electrode.

The first active layer A1 may include amorphous silicon or polycrystalline silicon. For example, the first active layer A1 may include a low-temperature polycrystalline silicon LTPS. For example, the polycrystalline silicon material has a high mobility (100 cm²/Vs or higher) so that energy power consumption is low and reliability is excellent. Therefore, the polysilicon material may be applied to a gate driver for driving elements which drive thin film transistors for a display element and/or a multiplexer (MUX) and also applied as an active layer A1 of a driving thin film transistor of the display device 100 according to the example implementation of the present disclosure, but is not limited thereto. For example, the polycrystalline silicon material may also be applied as the active layer A2 of the switching thin film transistor according to the characteristics of the display device 100. An amorphous silicon (a-Si) material is deposited on the first buffer layer 111 and a dehydrogenation process and a crystallization process are performed to form polycrystalline silicon and the polycrystalline silicon is patterned to form the first active layer A1. Here, the first active layer A1 may include a first channel region in which a channel is formed when the first thin film transistor T1 is driven and a first source region and a first drain region on both sides of the first channel region. The first source region refers to a part of the first active layer A1 which is connected to the first source electrode S1 and the first drain region refers to a part of the first active layer A1 which is connected to the first drain electrode D1. For example, the first source region and the first drain region may be configured by ion-doping (impurity doping) of the first active layer A1. The first source region and the first drain region may be generated by doping ions into the polycrystalline silicon material and the first channel region may refer to a part in which the ions are not doped, but the polycrystalline silicon material remains.

The first gate insulating layer 112a may be disposed on the first active layer A1. The first gate insulating layer 112a may be configured by a single layer of silicon nitride (SiNx) or silicon oxide (SiOx) or a multi-layer thereof. In the first gate insulating layer 112a, a contact hole through which the first source electrode S1 and the first drain electrode D1 of the first thin film transistor T1 are connected to the first source region and the first drain region of the first active layer A1 of the first thin film transistor T1, respectively, may be formed.

The first gate electrode G1 of the first thin film transistor T1 and a first capacitor electrode C1 of the storage capacitor Cst may be disposed on the first gate insulating layer 112a.

At this time, the first gate electrode G1 and the first capacitor electrode C1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 may be formed on the first gate insulating layer 112a so as to overlap the first channel region of the first active layer A1 of the first thin film transistor T1.

The first capacitor electrode C1 may be omitted based on a driving characteristic of the display device 100 and a structure and a type of the thin film transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed above the first gate insulating layer 112a, the first gate electrode G1, and the first capacitor electrode C1. The first interlayer insulating layer 113a may be configured by a single layer of silicon nitride SiNx or silicon oxide SiOx or a multi-layer thereof. In the first interlayer insulating layer 113a, a contact hole for exposing the first source region and the first drain region of the first active layer A1 of the first thin film transistor T1 may be formed.

A second capacitor electrode C2 of the storage capacitor Cst may be disposed on the first interlayer insulating layer 113a. The second capacitor electrode C2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display device 100 and a structure and a type of the thin film transistor.

The second buffer layer 114 may be disposed on the first interlayer insulating layer 113a and the second capacitor electrode C2. The second buffer layer 114 may be configured by a single layer of silicon nitride (SiNx) or silicon oxide (SiOx) or a multi-layer thereof. A contact hole for exposing the first source region and the first drain region of the first active layer A1 of the first thin film transistor T1 may be formed in the second buffer layer 114. Further, in the second buffer layer 114, a contact hole for exposing the second capacitor electrode C2 of the storage capacitor Cst may be formed.

The second buffer layer 114 may be formed by a multi-layer, but is not limited thereto.

The second active layer A2 of the second thin film transistor T2 may be disposed on the second buffer layer 114. Here, the second thin film transistor T2 may include a second active layer A2, a second gate insulating layer 112b, a second gate electrode G2, a second source electrode S2, and a second drain electrode D2. Here, depending on the design of the pixel circuit, the second source electrode S2 may serve as a drain electrode and the second drain electrode D2 may serve as a source electrode.

Further, the second active layer A2 may include a second channel region in which a channel is formed when the second thin film transistor T2 is driven and a second source region and a second drain region on both sides of the second channel region. The second source region may refer to a part of the second active layer A2 which is connected to the second source electrode S2 and the second drain region may refer to a part of the second active layer A2 which is connected to the second drain electrode D2.

The second active layer A2 may be formed of an oxide semiconductor. The oxide semiconductor material has a larger band gap than a silicon material so that electrons cannot jump over the band gap in an off state. Therefore, the oxide semiconductor material has a low off-current. Therefore, the thin film transistor including an active layer which is formed of an oxide semiconductor may be suitable for a switching thin film transistor which maintains on-time to be short and off-time to be long, but is not limited thereto. Depending on the characteristics of the display device 100, it may be applied as a driving thin film transistor. Further, due to the small off-current, a magnitude of an auxiliary capacitance may be reduced so that it may be appropriate for a high resolution display element. For example, the second active layer A2 may be formed of metal oxide and for example, may be formed of various metal oxides such as indium-gallium-zinc-oxide (IGZO). Here, the description was made under the assumption that the second active layer A2 of the second thin film transistor T2 is configured by IGZO, among various metal oxides, but the present disclosure is not limited thereto. Therefore, the second active layer may be formed of another metal oxide, such as indium-zinc-oxide (IZO), indium-gallium-tin-oxide (IGTO), or indium-gallium-oxide (IGO), rather than IGZO.

The second active layer A2 may be formed by depositing the metal oxide on the second buffer layer 114, performing a heat treatment for stabilization, and then patterning the metal oxide.

The second gate insulating layer 112b may be disposed on the entire substrate 110 including the second active layer A2. For example, the second gate insulating layer 112b may be configured by a single layer of silicon nitride SiNx or silicon oxide SiOx or a multi-layer thereof.

The second gate electrode G2 may be disposed on the second gate insulating layer 112b.

The second gate electrode G2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material may be used.

The second interlayer insulating layer 113b may be disposed on the second gate insulating layer 112b and the second gate electrode G2. A contact hole may be formed in the second interlayer insulating layer 113b for exposing the first active layer A1 of the first thin film transistor T1 and the second active layer A2 of the second thin film transistor T2. For example, a contact hole may be formed in the second interlayer insulating layer 113b for exposing the first source region and the first drain region of the first active layer A1 of the first thin film transistor T1. As another example, a contact hole may be formed in the second interlayer insulating layer 113b for exposing the second source region and the second drain region of the second active layer A2 of the second thin film transistor T2.

The second interlayer insulating layer 113b may be configured as a single layer of silicon nitride SiNx or silicon oxide SiOx or a multi-layer thereof.

A first connection electrode CE1, the first source electrode S1 and the first drain electrode D1 of the first thin film transistor T1 and the second source electrode S2 and the second drain electrode D2 of the second thin film transistor T2 may be disposed on the second interlayer insulating layer 113b.

The first connection electrode CE1 may be electrically connected to the second drain electrode D2 of the second thin film transistor T2. Further, the first connection electrode CE1 may be electrically connected to the second capacitor electrode C2 of the storage capacitor Cst through the contact holes formed in the second buffer layer 114, the second gate insulating layer 112b, and the second interlayer insulating layer 113b. As such, the first connection electrode CE1 may serve to electrically connect the second capacitor electrode C2 of the storage capacitor Cst and the second drain electrode D2 of the second thin film transistor T2 to each other.

In some implementations, the first source electrode S1 and the first drain electrode D1 of the first thin film transistor T1 may be connected to the first active layer A1 of the first thin film transistor T1 through the contact holes formed in the first gate insulating layer 112a, the first interlayer insulating layer 113a, the second buffer layer 114, the second gate insulating layer 112b, and the second interlayer insulating layer 113b.

The second source electrode S2 and the second drain electrode D2 of the second thin film transistor T2 may be connected to the second active layer A2 through the contact hole formed in the second gate insulating layer 112b and the second interlayer insulating layer 113b.

In some implementations, the first connection electrode CE1, the first source electrode S1 and the first drain electrode D1 of the first thin film transistor T1 and the second source electrode S2 and the second drain electrode D2 of the second thin film transistor T2 may be formed of the same material by the same process.

For example, the first connection electrode CE1, the first source electrode S1 and the first drain electrode D1 of the first thin film transistor T1 and the second source electrode S2 and the second drain electrode D2 of the second thin film transistor T2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the first connection electrode CE1, the first source electrode S1 and the first drain electrode D1 of the first thin film transistor T1 and the second source electrode S2 and the second drain electrode D2 of the second thin film transistor T2 may be formed of a triple layered structure of titanium (Ti)/aluminum (Al)/titanium (Ti), but are not limited thereto. The first connection electrode CE1 may be integrally formed to be connected to the second drain electrode D2 of the second thin film transistor T2, but is not limited thereto.

The first planarization layer 115a may be disposed above the first connection electrode CE1, the first source electrode S1 and the first drain electrode D1 of the first thin film transistor T1 and the second source electrode S2 and the second drain electrode D2 of the second thin film transistor T2, and the second interlayer insulating layer 113b.

The first planarization layer 115a may be an organic layer which planarizes and protects upper portions of the first thin film transistor T1 and the second thin film transistor T2. For example, the first planarization layer 115a may be formed of an organic material such as acryl resin, epoxy resin, phenolic resin, polyamide resin, or polyimide resin.

The second connection electrode CE2 may be disposed on the first planarization layer 115a. The second connection electrode CE2 may be connected to the second drain electrode D2 of the second thin film transistor T2 through the contact hole of the first planarization layer 115a. The second connection electrode CE2 may serve to electrically connect the second thin film transistor T2 and the anode 131 with each other. The second connection electrode CE2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The second connection electrode CE2 may be formed of the same material as the second source electrode S2 and the second drain electrode D2 of the second thin film transistor T2.

In some implementations, the auxiliary electrode AE may be disposed on the first planarization layer 115a. Referring back to FIG. 1, a plurality of auxiliary electrodes AE can be disposed across the display area DA. As an example, referring to FIG. 2, the auxiliary electrode AE can be disposed between the plurality of pixels PX. Further, referring to FIGS. 2 and 3, the auxiliary electrode AE can be disposed so as to overlap the dummy pixel DSP.

Referring to FIG. 3, the auxiliary electrode AE can be formed on the same layer with the same material as the second connection electrode CE2. For example, the auxiliary electrode AE may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The second planarization layer 115b can be disposed above the second connection electrode CE2, the auxiliary electrode AE, and the first planarization layer 115a. For example, the second planarization layer 115b may be formed of an organic material, such as acryl resin, epoxy resin, phenolic resin, polyamide resin, or polyimide resin.

The light emitting diode 130 including an anode 131, a common layer 132, an emission layer 133, and a cathode 134 may be disposed on the second planarization layer 115b. The light emitting diode 130 is disposed in each of a first sub pixel SP1, a second sub pixel SP2, and a third sub pixel SP3. Hereinafter, for the convenience of description, it is assumed that the light emitting diode 130 is an organic light emitting diode, but implementations of the present disclosure are not limited thereto.

The anode 131 can be disposed on the second planarization layer 115b. In some implementations, the anode 131 can be electrically connected to the second connection electrode CE2 through the contact hole provided in the second planarization layer 115b. The anode 131 may be formed of a metallic material. In scenarios where the display device 100 is a top emission type in which light emitted from the light emitting diode 130 is emitted above the substrate on which the light emitting diode 130 is disposed, the anode 131 can further include a transparent conductive layer and a reflective layer on the transparent conductive layer. The transparent conductive layer may be formed of transparent conductive oxide, such as ITO or IZO and for example, the reflective layer may be formed of silver (Ag), aluminum (Al), gold (Au), molybdenum (Mo), tungsten (W), chrome (Cr), or an alloy thereof.

In the area of the dummy pixel DSP, a dummy anode 135 can also be disposed on the second planarization layer 115b. In some implementations, the dummy anode 135 can be electrically connected to the auxiliary electrode AE through the contact hole provided in the second planarization layer 115b. The dummy anode 135 can be formed of a metallic material. Referring to the example of FIG. 3, the dummy anode 135 may be formed on the same layer with the same material as the anode 131.

A bank 116 is disposed on the anode 131, the dummy anode 135, and the planarization layer 115. The bank 116 covers edges of the anode 131 and the dummy anode 135 to form an open area, as shown in FIG. 3. According to the present disclosure, the bank 116 may be disposed in each of the plurality of sub-pixels. For example, in each sub pixel SP1, SP2, SP3, the bank 116 can cover an edge of the anode 131 of the light emitting diode 130 to define an emission area. As such, in some implementations, the bank 116 can be interposed between the plurality of sub pixels SP1, SP2, and SP3. For example, the bank 116 can be formed of an insulating material which insulates anodes 131 of adjacent sub pixels SP1, SP2, and SP3 from each other. In some implementations, the bank 116 may be formed of an opaque material (for example, black) in order to prevent light interference between adjacent pixels. In this case, the bank 116 may include a light shielding material constituted by at least one of a color pigment, organic black, or carbon, without being limited thereto. For example, the bank 116 may be configured by a black bank having a high light absorption rate to suppress color mixture between adjacent sub pixels SP1, SP2, and SP3. For example, the bank 116 may be formed of a polyimide resin, an acrylic resin, or a benzocyclobutene resin, but is not limited thereto.

Further, the bank 116 also covers an edge of the dummy anode 135 in the dummy pixel DSP to define an open area. As described below, in forming the dummy anode 135, laser is irradiated to remove an organic layer thereabove. In this case, the edge of the dummy anode 135 forms a structure covered by the bank 116.

In contrast to the above-described laser process, if instead a high temperature voltage is applied to the dummy anode 135, then all organic layers disposed on the dummy anode 135 are removed due to the heat generated in the dummy anode 135 by applying the high temperature voltage to the dummy anode 135. In such scenarios, when the dummy anode 135 and the cathode 134 are in contact with each other, the bank 116 located in the edge of the dummy anode 135 is also removed together with the organic layer, thus exposing the edge of the dummy anode 135. When the edge of the dummy anode 135 is exposed, problems can occur where the exposed edge of the dummy anode 135 can irregularly reflect external light which is incident into the display device 100 through an opening defined by the black matrix 163 of the anti-reflection layer 160, described below. In such scenarios, the reflective luminosity of the display device 100 may be degraded by the irregularly reflected light.

In the display device 100 according to implementations of the present disclosure, the organic layers disposed above the dummy anode 135 are removed by the laser process. However, the laser process can provide a benefit in that the bank 116 which encloses the dummy anode 135 is not removed so that the edge of the dummy anode 135 remains covered by the bank 116, and a corner of the dummy anode 135 is exposed to maintain a flat top surface of the dummy anode 135 without forming a step. Therefore, the external light which is reflected by the dummy anode 135 is not irregularly reflected, but may be reflected in a more consistent manner.

The cathode 134 is disposed on the anode 131 and the dummy anode 135. The cathode 134 may be formed of a metal material having a low work function to smoothly supply electrons to the emission layer 133. For example, the cathode 134 may be formed of a metal material selected from calcium (Ca), barium (Ba), aluminum (Al), silver (Ag), and alloys including one or more of them, but is not limited thereto. In some implementations, the cathode 134 may be formed on the anode 131 as one layer. For example, the cathode 134 may be formed in the first sub pixel SP1, the second sub pixel SP2, and the third sub pixel SP3 as a single layer. When the display device 100 is driven as a top emission type, the cathode 134 is formed to have a very small thickness to be substantially transparent.

The emission layer 133 is disposed between the anode 131 and the cathode 134. The emission layer 133 is a layer in which electrons and holes are coupled to emit light. For example, an emission layer of the light emitting diode of the first sub pixel SP1 may be a red organic emission layer, an emission layer of the light emitting diode of the second sub pixel SP2 may be a green organic emission layer, and an emission layer of the light emitting diode of the third sub pixel SP3 may be a blue organic emission layer.

In order to improve luminous efficiency of the light emitting diode 130, a common layer 132 including a hole injection layer, a hole transport layer, an electron transport layer, and an electron injection layer may be further included. For example, the hole injection layer and the hole transport layer may be disposed between the anode 131 and the emission layer 133 and the electron transport layer and the electron injection layer may be disposed between the emission layer 133 and the cathode 134. Further, a hole blocking layer or an electron blocking layer may be disposed to further improve a recombination efficiency of the holes and electrons in the emission layer 133. The common layer 132 is disposed not only in the first sub pixel SP1, the second sub pixel SP2, and the third sub pixel SP3, but also in the dummy pixel DSP. Even though the example of FIG. 3 shows a structure in which the common layer 132 is disposed below the emission layer 133, the common layer 132 may be disposed above the emission layer 133 or may be simultaneously disposed below and above the emission layer 133.

Referring to FIG. 3, in the first sub pixel SP1, the light emitting diode 130 includes an anode 131, a common layer 132, an emission layer 133, and a cathode 134. In this example of the first sub pixel SP1, the common layer 132 is disposed between the anode 131 and the emission layer 133. The common layer 132 extends not only to the first sub pixel SP1, but also to the second sub pixel SP2 and the third sub pixel SP3 to be commonly disposed.

Moreover, the common layer 132 extends toward the dummy pixel DSP. For example, the common layer 132 extends to the dummy anode 135, and may at least partially overlap the dummy anode 135. In some implementations, as shown in FIG. 3, the common layer 132 may include a through hole which exposes at least a part of the dummy anode 135 in the dummy pixel DSP. As such, the common layer 132 may not be disposed on at least a portion of the dummy anode 135. In other words, at least a portion of the dummy anode 135 may not be covered by the common layer 132. Moreover, FIG. 3 illustrates a structure in which the common layer 132 is disposed on a side surface of the bank 116 adjacent to the dummy pixel DSP, and the common layer 132 is in direct contact with a part of the dummy anode 135., However, implementations of the present disclosure are not limited thereto, and in some implementations the common layer 132 may not be in contact with the dummy anode 135. In the display device 100 of FIG. 3 according to the example implementation of the present disclosure, in the dummy pixel DSP, the cathode 134 and the dummy anode 135 are in contact with each other to be electrically connected to the auxiliary electrode AE. For example, in order to connect the dummy anode 135 and the cathode 134, laser can be irradiated onto the dummy anode 135. By doing this, a part of the common layer 132 located on a path of the laser is removed to form the through hole in the common layer 132.

The encapsulation layer 140 is disposed on the light emitting diode 130 and the bank 116. The encapsulation layer 140 can cover the light emitting diode 130 and, in some implementations, the encapsulation layer 140 can protect the light emitting diode 130 from moisture, oxygen, and impacts of the outside. The encapsulation layer 140 may be formed with a multi-layered structure in which an inorganic layer formed of an inorganic insulating material and an organic layer formed of an organic material are laminated. For example, the encapsulation layer 140 may be configured by at least one organic layer and at least two inorganic layers and have a multi-layered structure in which the inorganic layers and the organic layer are alternately laminated, but is not limited thereto. For example, as shown in FIG. 3, the encapsulation layer 140 may have a triple layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but are not limited thereto. Further, the organic layer 142 may be formed of one or more selected from epoxy resin, polyimide, polyethylene, and silicon oxycarbide (SiOC), but is not limited thereto.

Meanwhile, the encapsulation layer 140 is not limited to three or five layers, for example, n layers alternately stacked between inorganic encapsulation layer and organic encapsulation layer (where n is an integer greater than 3) may be included.

The touch sensor structure 150 can be disposed on the encapsulation layer 140 to impart a touch sensing function to the display device 100. The display device 100 according to the example implementation of the present disclosure includes a touch sensor structure 150 in which the touch electrode 151 is formed on the encapsulation layer 140. This is in contrast to an alternative structure of a touch panel in which a touch electrode is formed on a separate base member is disposed above the organic light emitting diode by means of the adhesive member. Instead, the touch sensor structure 150 is directly formed on the encapsulation layer 140, thus making it possible to omit an adhesive member which attaches the touch sensor structure 150 and the display panel, and thereby reducing the thickness of the display device 100. However, implementations are not limited thereto, and in some implementations the touch sensor structure 150 can be omitted from the display device 100.

The touch sensor structure 150 includes a touch electrode 151 and a touch protection layer 152. The touch electrode 151 may be directly formed on the encapsulation layer 140 without using an adhesive member. The touch electrode 151 is an electrode which senses a touch input and may be configured by a sensing electrode and a driving electrode and may detect a touch coordinate by sensing a change of the capacitance between the sensing electrode and the driving electrode. For example, the driving electrode may be disposed on the second inorganic layer 143 and the sensing electrode may be disposed on the same plane as the driving electrode. As another example, a touch insulating layer may be disposed on the driving electrode and the sensing electrode may be disposed on the touch insulating layer. The placement of the touch electrode 151 is not limited thereto and may vary as needed.

The touch electrode 151 is directly formed on the encapsulation layer 140 so that a distance between the light emitting diode 130 and the touch electrode 151 is too close. Therefore, a parasitic capacitance is generated between the electrode included in the light emitting diode 130 or the thin film transistor TFT and the touch electrode 151 so that the touch sensitivity may be degraded. Therefore, the thickness of the encapsulation layer 140 may be appropriately adjusted to minimize the parasitic capacitance.

The touch electrode 151 may be formed of a transparent metal material which transmits the light, such as indium tin oxide (ITO) or indium zinc oxide (IZO). The touch electrode 151 may have various shapes such as a rectangular shape, an octagonal shape, a circular shape, or a rhombus shape.

The touch protection layer 152 is disposed on the touch electrode 151. The touch protection layer 152 suppresses the short-circuit or damage of the touch electrode 151 and planarizes an upper surface of the touch electrode 151. The touch protection layer 152 may be formed of a transparent insulating resin such as an acrylic resin, a polyester resin, an epoxy resin, or a silicon resin.

FIG. 3 illustrates a structure in which the touch electrode 151 of the touch sensor structure 150 is in direct contact onto the encapsulation layer 140, but implementations the present disclosure are not limited thereto. For example, the touch buffer layer may be disposed between the encapsulation layer 140 and the touch sensor structure 150 and the touch electrode 151 may be disposed on the touch buffer layer. The touch buffer layer may suppress the damage of the encapsulation layer 140 and the light emitting diode 130 during a process of directly forming the touch electrode 151 on the encapsulation layer 140. The touch buffer layer may be formed of an inorganic material having an excellent barrier property. Therefore, the permeation of moisture or oxygen may be minimized. For example, the touch buffer layer may be formed of an inorganic material, such as silicon nitride SiNx, silicon oxide SiOx, or aluminum oxide AlOx, but is not limited thereto.

The anti-reflection layer 160 can be disposed on the touch sensor structure 150. The anti-reflection layer 160 can include a plurality of color filters 162a, 162b, 162c, 162d (as shown in FIG. 2, of which color filters 162a, 162d are shown in FIG. 3) and a black matrix 163. The plurality of color filters 162a, 162b, 162c, and 162d and the black matrix 163 may serve as an anti-reflection layer which absorbs external light to minimize the degradation of visibility and a contrast ratio of the display device 100 due to the external light.

The black matrix 163 is disposed on the encapsulation layer 140. The black matrix 163 may be disposed on the touch sensor structure 150 or the third buffer layer 161. In some implementations, the third buffer layer 161 suppresses the permeation of the moisture or oxygen from the outside to protect the components of the display device 100. The third buffer layer 161 may be formed of an inorganic material having an excellent barrier property. Therefore, the permeation of moisture or oxygen may be minimized. For example, the third buffer layer 161 may be formed of one or more inorganic materials selected from silicon nitride (SiNx), silicon oxide (SiOx), silicon oxy nitride (SiON), and aluminum oxide (Al2O3), but is not limited thereto. Further, the third buffer layer 161 may compensate for degradation of an adhesive strength between the plurality of color filters 162a, 162b, 162c, and 162d and the black matrix 163 and the touch protection layer 152. In some implementations, the third buffer layer 161 may be omitted in scenarios where the touch sensor structure 150 is disposed above the encapsulation layer 140 by an adhesive member or is disposed below the encapsulation layer 140.

The black matrix 163 is disposed along the boundary of the sub pixels SP1, SP2, and SP3 and the dummy pixel DSP and includes openings which expose the sub pixels SP1, SP2, and SP3 and the dummy pixel DSP. The black matrix 163 is interposed between the plurality of color filters 162a, 162b, 162c, and 162d. The black matrix 163 can be disposed so as to overlap the bank 116. As such, problems of color mixture between the sub pixels SP1, SP2, and SP3 may be minimized. Further, the black matrix 163 may absorb external light. Therefore, the degradation of the visibility and the contrast ratio of the display device 100 due to the external light may be minimized.

In some implementations, the size of the above-described openings may vary in each of the sub pixels SP1, SP2, and SP3. For example, a size of the opening defined by the black matrix 163 may correspond to a size of the open area defined by the bank 116. The size of the opening and the size of the open area may vary, e.g., depending on respective lifespans of the light emitting diodes 130 of the sub pixels SP1, SP2, and SP3. For example, a size of an opening and a size of an open area of the red sub pixel may be smaller than a size of an opening and a size of an open area of the green sub pixel. Further, the black matrix 163 can absorb external light. Therefore, the degradation of the visibility and the contrast ratio of the foldable display device 100 due to the external light may be minimized.

The black matrix 163 may be made of a material with high optical density (OD). Hence, the black matrix 163 may absorb or block light. The black matrix 163 may be formed of an organic material. The black matrix 163 includes a base resin and a black material. The base resin may be one or more selected from cardo-based resin, epoxy-based resin, acrylate-based resin, siloxane-based resin, and polyimide, but is not limited thereto. The black material may be a black pigment selected from a carbon-based pigment, a metal oxide-based pigment, and an organic pigment. For example, the carbon-based pigment may be carbon black. For example, the metal oxide-based pigment may be titanium black (TiNxOy) or Cu-Mn-Fe-based black pigment, but is not limited thereto. For example, the organic pigment may be selected from lactam black, perylene black, and aniline black, but is not limited thereto. Further, as the black material, a RGB black pigment including a red pigment, a blue pigment, and a green pigment may be used.

The plurality of color filters 162a, 162b, 162c, and 162d are disposed on the encapsulation layer 140. The plurality of color filters 162a, 162b, 162c, and 162d may be disposed on the touch sensor structure 150 or the third buffer layer 161. Further, the plurality of color filters 162a, 162b, 162c, and 162d may be disposed to be in direct contact with the third buffer layer 161 and may be disposed to cover a partial area of the black matrix 163. The plurality of color filters 162a, 162b, 162c, and 162d absorbs external light to minimize degradation of the visibility and the contrast ratio due to the external light and improve a color reproductivity. The plurality of color filters 162a, 162b, 162c, and 162d is disposed on the encapsulation layer 140 to improve the luminous efficiency and can enable the display device 100 to be implemented without a polarization plate.

The plurality of color filters 162a, 162b, 162c, and 162d is disposed so as to correspond to the plurality of sub pixels SP1, SP2, and SP3 and the dummy pixel DSP disposed therebelow. For example, the plurality of color filters 162a, 162b, 162c, and 162d includes a first color filter 162a corresponding to the first sub pixel SP1, a second color filter 162b corresponding to the second sub pixel SP2, a third color filter 162c corresponding to the third sub pixel SP3, and a fourth color filter 162d corresponding to the dummy pixel DSP. In some implementations, the first color filter 162a, the second color filter 162b, and the third color filter 162c may correspond to colors of corresponding sub pixels, respectively. As such, the first color filter 162a, the second color filter 162b, and the third color filter 162c may have colors corresponding to the first sub pixel SP1, the second sub pixel SP2, and the third sub pixel SP3 each representing one color. For example, when the first sub pixel SP1 is a red sub pixel, the first color filter 162a is a red color filter and transmits red light. When the second sub pixel SP2 is a green sub pixel, the second color filter 162b is a green color filter and transmits green light. When the third sub pixel SP3 is a blue sub pixel, the third color filter 162c is a blue color filter and transmits blue light. In some implementations, a wavelength of the red light may be approximately 620 nm to 750 nm, a wavelength of the green light may be approximately 495 nm to 570 nm, and a wavelength of the blue light may be approximately 440 nm to 495 nm.

The first color filter 162a, the second color filter 162b, and the third color filter 162c are disposed so as to correspond to colors of the corresponding first sub pixel SP1, second sub pixel SP2, and third sub pixel SP3. Therefore, internal light emitted from each of the first sub pixel SP1, the second sub pixel SP2, and the third sub pixel SP3 transmits the first color filter 162a, the second color filter 162b, and the third color filter 162c. For example, red light emitted from the first sub pixel SP1 passes through the first color filter 162a. In contrast, when external light is incident, the external light corresponding to an absorption wavelength of a color development material included in each of the first color filter 162a, the second color filter 162b, and the third color filter 162c is absorbed by the each color filter. The external light which is not absorbed by the first color filter 162a, the second color filter 162b, and the third color filter 162c is reflected from the cathode 134 to transmit through the color filter again. Reflected light corresponding to an absorption wavelength of the color development material included in each color filter 162a, 162b, 162c, 162d is absorbed by each color filter 162a, 162b, 162c, 162d. Therefore, the degradation of the display quality due to the external light may be minimized.

In some implementations, the fourth color filter 162d corresponds to the dummy pixel DSP. As described above, the dummy pixel DSP does not emit a color, but instead connects the auxiliary electrode AE and the cathode 134. In some implementations, the fourth color filter 162d may correspond to a color corresponding to any one of the first sub pixel SP1, the second sub pixel SP2, and the third sub pixel SP3. For example, the fourth color filter 162d may have a color corresponding to the first sub pixel SP1 which represents red and may be a red color filter, like the first color filter 162a.

Similar to the first to third color filters 162a, 162b, and 162c, the fourth color filter 162d absorbs external light corresponding to the absorption wavelength of the color development material included in the fourth color filter 162d and the external light which is not absorbed is reflected from the cathode to be emitted again. In some implementations, the fourth color filter 162d may adjust the reflective luminosity when the display device 100 is not driven.

Specifically, in the display device 100 according to the example implementation of the present disclosure, the lifespan of the light emitting diode 130 varies depending on the material which configures the emission layer 133 in each of the first to third sub pixels SP1, SP2, and SP3. Therefore, in some implementations, the size of the opening defined by the black matrix 163 and the size of the open area defined by the bank 116 vary in each of the first to third sub pixels SP1, SP2, and SP3. The first to third color filters 162a, 162b, and 162c are disposed in the openings defined by the black matrix 163 to have different sizes. However, in scenarios where the opening has a different size in each of the first to third sub pixels SP1, SP2, and SP3 which represent different colors, the reflective luminosity when the display device 100 is not driven may be shifted as much as an area ratio of the opening. For example, as illustrated in FIG. 2, the area of the opening of the first sub pixel SP1 which is a red sub pixel having the most excellent luminous efficiency is the smallest and a sum of the areas of the openings of two third sub pixels SP3 which are blue sub pixels may be the largest. In such scenarios, when the display device 100 is not driven, the area of the color filter through which external light reflected by the cathode 134 passes is the largest and the red sub pixel is the smallest so that a color coordinate of the reflected light is shifted to bluish. That is, the display device 100 in a non-driven state has a bluish color due to the external light reflection so that the reflective luminosity may be degraded.

In some implementations, the fourth color filter 162d is implemented to have the same color as a color filter having the smallest opening, which can help to improve the reflective luminosity. For example, as described above, when the area of the opening of the first sub pixel SP1 which is the red sub pixel is the smallest, the fourth color filter 162d has the same color as the first color filter 162a of the first sub pixel SP1. This can help to shift the color coordinate of the reflected light to have a luminosity closer to the neutral black. However, the fourth color filter 162d is not limited to the red color filter, but may be implemented to have the same color as the color filter of the sub pixel having the smallest opening, among the first to third sub pixels SP1, SP2, and SP3.

Each color filter 162a, 162b, 162c, 162d includes a transparent base resin and a color development material. For example, the transparent base resin may be one selected from polyacrylate, polymethyl methacrylate, polyimide, polyvinyl alcohol, polyethylene, polypropylene, polystyrene, and polyethylene terephthalate, but is not limited thereto.

An over coating layer 164 may be disposed on the plurality of color filters 162a, 162b, 162c, and 162d and the black matrix 163. The over coating layer 164 may planarize upper portions of the plurality of color filters 162a, 162b, 162c, and 162d and the black matrix 163. The over coating layer 164 may be formed of transparent resin, such as acrylic resin, silicon-based resin, polyester-based resin, and epoxy resin, but is not limited thereto.

In some implementations, the over coating layer 164 may include a UV absorbing layer. The UV absorbing layer blocks light with ultraviolet wavelength from external light incident to the display device 100. The UV absorbing layer blocks light with a wavelength which is equal to or lower than 400 nm and transmits visible ray with a wavelength which exceeds approximately 400 nm. The UV absorbing layer may be formed of an organic material including a UV blocker or a UV absorber which blocks or absorbs light with a wavelength which is equal to or lower than 400 nm. The UV blocker or UV absorber may be used without limitation as long as the UV blocker or UV absorber is a material used in this technical field.

The foldable display device according to the example implementation of the present disclosure includes a dummy pixel to which a cathode and an auxiliary electrode are connected. In the dummy pixel, the organic layer on the dummy anode is removed by the laser process and the cathode and the dummy anode are in contact with each other so that the cathode is electrically connected to the auxiliary electrode located below the dummy anode. In some implementations, only the organic layer above the dummy anode is removed by the laser process, but the bank is not removed so that the edge of the dummy anode remains enclosed by the bank, like the normal anode. This process can help avoid a step from being formed on the top surface of the dummy anode, which can help suppress irregular reflection of external light. Further, the anti-reflection layer including a color filter is formed above the dummy pixel. The color filter corresponding to the dummy pixel may be configured to be the same as a color filter of a sub pixel having the smallest opening defined by the black matrix, among sub pixels which represent colors. By doing this, when the display device is not driven, the reflective luminosity is suppressed from being shifted to a specific color to improve the overall reflective luminosity.

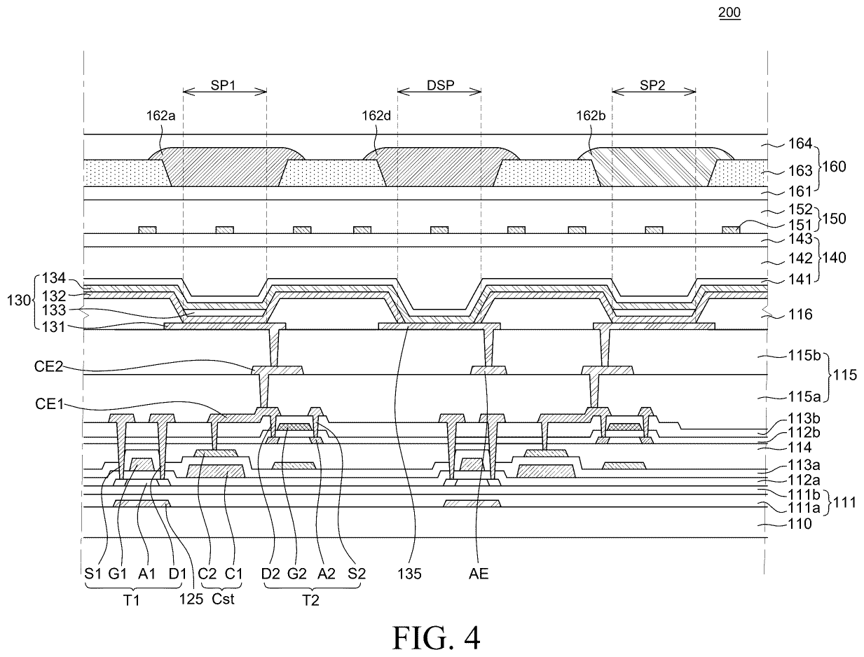

FIG. 4 is a schematic cross-sectional view of an example of a display device according to another example implementation of the present disclosure. A display device 200 illustrated in FIG. 4 has substantially the same configurations as the display device 100 illustrated in FIGS. 1 to 3 except that a structure of a second sub pixel is further illustrated, so that a redundant description will be omitted.

In FIG. 4, cross-sections of a first sub pixel SP1, a second sub pixel SP2, and a dummy pixel DSP are illustrated. The third sub pixel SP3 may have substantially the same structure as any one of the first sub pixel SP1 and the second sub pixel SP2 except for light that is output from an emission stack which configures the light emitting diode 130.

In each of the first sub pixel SP1 and the second sub pixel SP2, a plurality of thin film transistors T1 and T2 may be disposed above the substrate 110. The planarization layer 115 may be disposed above the thin film transistors T1 and T2. The light emitting diode 130 may be disposed above the planarization layer 115, the encapsulation layer 140 may be disposed above the light emitting diode 130, and the touch sensing structure 150 and the anti-reflection layer 160 may be disposed above the encapsulation layer 140.

In some implementations, in the second sub pixel SP2, at least a part of the thin film transistors T1 and/or T2 connected to the light emitting diode of the second sub pixel SP2 can be disposed to overlap an adjacent dummy pixel DSP. For example, referring to FIG. 4, the first thin film transistor T1 of the second sub pixel SP2 may overlap the dummy pixel DSP and overlap the dummy anode 135 and the auxiliary electrode AE located in the dummy pixel DSP. FIG. 3 illustrates a structure in which only the first thin film transistor T1 of the second sub pixel SP2 overlaps the dummy pixel DSP, but implementations of the present disclosure are not limited thereto. For example, at least a part of the storage capacitor Cst or the second thin film transistor T2 of the second sub pixel SP2 may also overlap the dummy pixel DSP.

At least a part of the thin film transistors T1 and T2 of the second sub pixel SP2 overlaps the dummy pixel DSP so that a width of the black matrix which encloses the second sub pixel SP2 may be reduced and a size of the opening of the second sub pixel SP2 may be increased. For example, when the second sub pixel SP2 is a green sub pixel, the size of the opening of the second sub pixel SP2 may be adjusted in consideration of the lifespan of the light emitting diode of the green sub pixel.

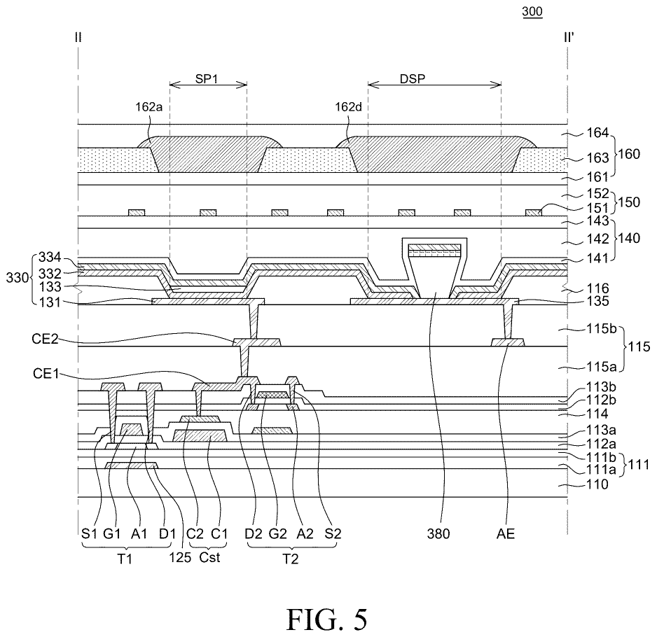

FIG. 5 is a schematic cross-sectional view of an example of a display device according to still another implementation of the present disclosure. A display device 300 illustrated in FIG. 5 has substantially the same configurations as the display device 100 illustrated in FIGS. 1 to 3 except that a structure in a dummy pixel DSP and the light emitting diode 330 is different, so that a redundant description will be omitted.

Referring to FIG. 5, a partition 380 is disposed on the dummy anode 135 in the dummy pixel DSP. The partition 380 is formed, for example, in a reverse tapered shape. The reverse tapered shape means that a width of the partition 380 is increased as it goes away upwardly from the substrate 110. A bottom surface of the partition 380 is in contact with a partial area of the dummy anode 135 and an area of the top surface of the partition 380 is configured to be larger than an area of the bottom surface of the partition 380. In this case, a shadow is generated below the partition 380 due to the reverse tapered shape of the partition 380. In some implementations, the common layer 332 may be formed by deposing an organic material so as to cover all the anode 131 of the first sub pixel SP1 and the dummy anode 135 of the dummy pixel DSP. Generally, the organic material is configured by a material having a step coverage which may not be excellent. Due to the relatively inferior step coverage of the organic material, the organic material is not deposited in the region directly under the overhang caused by the reverse tapered shape of the partition 380. Accordingly, a top surface of the dummy anode 135 may be exposed in the vicinity of the boundary of the partition 380 and a physical space in which the dummy anode 135 and the cathode 334 are electrically connected may be ensured in the vicinity of the boundary of the partition 380. Thereafter, the cathode 334 may be deposited. In some implementations, the cathode 334 may be deposited to be in partially contact with the top surface of the dummy anode 135 exposed in the region under the overhang caused by the reverse tapered shape of the partition 380. Accordingly, the cathode 334 may be electrically connected to the dummy anode 135.

In the display device 300 illustrated in FIG. 5, a partition 380 which causes the cathode 334 and the dummy anode 135 to be in contact with each other is disposed in the dummy pixel DSP. By doing this, the auxiliary electrode AE of the dummy anode 135 is connected to the cathode in the display area DA to apply a uniform common voltage to the entire display area DA with a large area. Further, the anti-reflection layer including a color filter disposed above the dummy pixel DSP allows reflected light by the cathode 334 in the dummy pixel DSP to pass through the color filter. By doing this, when the display device is not driven, the reflective luminosity is suppressed from being shifted to a specific color to improve the overall reflective luminosity.

The example implementations of the present disclosure can also be described as follows:

According to an aspect of the present disclosure, there is provided a display device. The display device comprises a substrate in which a plurality of sub pixels and a plurality of dummy pixels are defined, an anode which is disposed on the substrate and is disposed to correspond to each of the plurality of sub pixels, a dummy anode which is disposed on the substrate and is disposed to correspond to each of the plurality of dummy pixels, an auxiliary electrode which is disposed below the dummy anode and is electrically connected to the dummy anode, a bank which covers an edge of the anode to define an open area above the anode, a cathode disposed on the anode and the dummy anode, an encapsulation layer on the cathode, a plurality of color filters disposed on the encapsulation layer and corresponding to the plurality of sub pixels and the plurality of dummy pixels, and a black matrix interposed between adjacent color filters of the plurality of color filters.

The display device may further comprise a thin film transistor disposed on the substrate, a first planarization layer disposed on the thin film transistor, a connection electrode disposed on the first planarization layer and passing through the first planarization layer to be connected to the thin film transistor, and a second planarization layer disposed on the connection electrode. The auxiliary electrode may be disposed on the first planarization layer.

The auxiliary electrode may be connected to the dummy anode through a through hole in the second planarization layer, and the auxiliary electrode may be formed of the same material as the connection electrode.

The display device may further comprise an emission layer disposed on the anode to correspond to each of the plurality of sub pixels, and a common layer disposed above or below the emission layer. The common layer may extend toward the plurality of dummy pixels, and the emission layer may be not disposed in the plurality of dummy pixels.

The common layer may include a through hole formed in the dummy anode and in the dummy pixel, and the dummy anode and the cathode may be in direct contact with each other.

The bank may be in direct contact with the dummy anode to cover an edge of the dummy anode.

The cathode may have a flat shape in an area overlapping the dummy anode in each of the plurality of dummy pixels.

The plurality of sub pixels may include a first sub pixel, a second sub pixel, and a third sub pixel which emit different color light, the plurality of color filters may include a first color filter corresponding to the first sub pixel, a second color filter corresponding to the second sub pixel, a third color filter corresponding to the third sub pixel, and a fourth color filter corresponding to the plurality of dummy pixels, and the fourth color filter may be formed of the same material as the first color filter.

The black matrix may include openings corresponding to each of the first sub pixel, the second sub pixel, the third sub pixel, and the plurality of dummy pixels, and the fourth color filter may be formed of the same material as a color filter of a sub pixel having an opening with the smallest size, among the first sub pixel, the second sub pixel, and the third sub pixel.

The first sub pixel may be a red sub pixel, the second sub pixel is a green sub pixel, and the third sub pixel is a blue sub pixel, and the fourth color filter may be a red color filter.

The display device may further comprise a partition disposed on the dummy anode to at least partially overlap the dummy anode. The partition may have a reverse tapered shape.

A first portion of the cathode may be disposed on the partition, and a second portion of the cathode may be in direct contact with the dummy anode below the partition.

The plurality of sub pixels may include a first sub pixel, a second sub pixel, and a third sub pixel which emit different color light, and a thin film transistor of any one sub pixel of the first sub pixel, the second sub pixel, and the third sub pixel may be disposed so as to overlap a dummy pixel among the plurality of dummy pixels.

According to an another aspect of the present disclosure, there is provided a display device. The display device comprises a substrate in which a display area and a non-display area outside a periphery of the display area are defined, a common voltage line disposed in the non-display area and configured to apply a common voltage to the display area, an auxiliary electrode disposed across the display area and electrically connected to the common voltage line, a first sub pixel including a first light emitting diode with a first anode, and further including a first pixel circuit connected to the first light emitting diode, a second sub pixel including a second light emitting diode with a second anode, and further including a second pixel circuit connected to the second light emitting diode, a third sub pixel including a third light emitting diode with a third anode, and further including a third pixel circuit connected to the third light emitting diode, a dummy pixel including a dummy anode connected to the auxiliary electrode, and an anti-reflection layer including a first color filter overlapping the first anode, a second color filter overlapping the second anode, a third color filter overlapping the third anode, and a fourth color filter overlapping the dummy anode.

The fourth color filter may be formed of the same material as the first color filter.

Each of the first light emitting diode, the second light emitting diode, and the third light emitting diode may further include an emission layer configured to emit different color light for each sub pixel, a common layer which commonly overlaps the first light emitting diode, the second light emitting diode, and the third light emitting diode, and a cathode which commonly overlaps the first light emitting diode, the second light emitting diode, and the third light emitting diode. The dummy pixel may include the common layer and the cathode.

The dummy anode may be disposed on the same layer as the first anode, the second anode, and the third anode.

According to yet another aspect of the present disclosure, there is provided a display device. The display device, comprises a substrate in which light-emitting sub pixels and non-light-emitting pixels are defined, a first anode disposed on the substrate and corresponding to each of the light-emitting sub pixels, a second anode disposed on the substrate and corresponding to each of the non-light-emitting pixels, an auxiliary electrode disposed below and electrically connected to the second anode of the non-light-emitting pixels, a bank that covers edges of first anode and edges of the second anode, and that has first openings between the covered edges of the first anode and second openings between the covered edges of the second anode, a cathode disposed above the first anode and the second anode, and electrically connected to the second anode, first color filters corresponding to the first openings in the bank above the first anode of the light-emitting sub pixels; and second color filters corresponding to the second openings in the bank above the second anode of the non-light-emitting pixels.

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate in which a plurality of sub pixels and a plurality of dummy pixels are defined;
an anode which is disposed on the substrate and is disposed to correspond to each of the plurality of sub pixels;
a dummy anode which is disposed on the substrate and is disposed to correspond to each of the plurality of dummy pixels;
an auxiliary electrode which is disposed below the dummy anode and is electrically connected to the dummy anode;
a bank which covers an edge of the anode to define an open area above the anode;
a cathode disposed on the anode and the dummy anode;
an encapsulation layer on the cathode;
a plurality of color filters disposed on the encapsulation layer and corresponding to the plurality of sub pixels and the plurality of dummy pixels; and
a black matrix interposed between adjacent color filters of the plurality of color filters.

2. The display device according to claim 1, further comprising:
a thin film transistor disposed on the substrate;
a first planarization layer disposed on the thin film transistor;
a connection electrode disposed on the first planarization layer and passing through the first planarization layer to be connected to the thin film transistor; and
a second planarization layer disposed on the connection electrode,
wherein the auxiliary electrode is disposed on the first planarization layer.

3. The display device according to claim 2, wherein the auxiliary electrode is connected to the dummy anode through a through hole in the second planarization layer, and the auxiliary electrode is formed of the same material as the connection electrode.

4. The display device according to claim 1, further comprising:
an emission layer disposed on the anode to correspond to each of the plurality of sub pixels; and
a common layer disposed above or below the emission layer,
wherein the common layer extends toward the plurality of dummy pixels, and
wherein the emission layer is not disposed in the plurality of dummy pixels.

5. The display device according to claim 4, wherein the common layer includes a through hole formed in the dummy anode and in the dummy pixel, and
wherein the dummy anode and the cathode are in direct contact with each other.

6. The display device according to claim 1, wherein the bank is in direct contact with the dummy anode to cover an edge of the dummy anode.

7. The display device according to claim 6, wherein the cathode has a flat shape in an area overlapping the dummy anode in each of the plurality of dummy pixels.

8. The display device according to claim 1, wherein the plurality of sub pixels includes a first sub pixel, a second sub pixel, and a third sub pixel which emit different color light,
the plurality of color filters includes a first color filter corresponding to the first sub pixel, a second color filter corresponding to the second sub pixel, a third color filter corresponding to the third sub pixel, and a fourth color filter corresponding to the plurality of dummy pixels, and
the fourth color filter is formed of the same material as the first color filter.

9. The display device according to claim 8, wherein the black matrix includes openings corresponding to each of the first sub pixel, the second sub pixel, the third sub pixel, and the plurality of dummy pixels, and
the fourth color filter is formed of the same material as a color filter of a sub pixel having an opening with the smallest size, among the first sub pixel, the second sub pixel, and the third sub pixel.

10. The display device according to claim 8, wherein the first sub pixel is a red sub pixel, the second sub pixel is a green sub pixel, and the third sub pixel is a blue sub pixel, and
wherein the fourth color filter is a red color filter.

11. The display device according to claim 1, further comprising:
a partition disposed on the dummy anode to at least partially overlap the dummy anode,
wherein the partition has a reverse tapered shape.

12. The display device according to claim 11, wherein a first portion of the cathode is disposed on the partition, and
wherein a second portion of the cathode is in direct contact with the dummy anode below the partition.

13. The display device according to claim 2, wherein the plurality of sub pixels includes a first sub pixel, a second sub pixel, and a third sub pixel which emit different color light, and
wherein a thin film transistor of any one sub pixel of the first sub pixel, the second sub pixel, and the third sub pixel is disposed so as to overlap a dummy pixel among the plurality of dummy pixels.

14. A display device, comprising:
a substrate in which a display area and a non-display area outside a periphery of the display area are defined;
a common voltage line disposed in the non-display area and configured to apply a common voltage to the display area;
an auxiliary electrode disposed across the display area and electrically connected to the common voltage line;
a first sub pixel including a first light emitting diode with a first anode, and further including a first pixel circuit connected to the first light emitting diode;
a second sub pixel including a second light emitting diode with a second anode, and further including a second pixel circuit connected to the second light emitting diode;
a third sub pixel including a third light emitting diode with a third anode, and further including a third pixel circuit connected to the third light emitting diode;
a dummy pixel including a dummy anode connected to the auxiliary electrode; and
an anti-reflection layer including a first color filter overlapping the first anode, a second color filter overlapping the second anode, a third color filter overlapping the third anode, and a fourth color filter overlapping the dummy anode.

15. The display device according to claim 14, wherein the fourth color filter is formed of the same material as the first color filter.

16. The display device according to claim 14, wherein each of the first light emitting diode, the second light emitting diode, and the third light emitting diode further includes:
an emission layer configured to emit different color light for each sub pixel;
a common layer which commonly overlaps the first light emitting diode, the second light emitting diode, and the third light emitting diode; and
a cathode which commonly overlaps the first light emitting diode, the second light emitting diode, and the third light emitting diode; and
wherein the dummy pixel includes the common layer and the cathode.

17. The display device according to claim 16, wherein the dummy anode is disposed on the same layer as the first anode, the second anode, and the third anode.

18. A display device, comprising:
a substrate in which light-emitting sub pixels and non-light-emitting pixels are defined;
a first anode disposed on the substrate and corresponding to each of the light-emitting sub pixels,
a second anode disposed on the substrate and corresponding to each of the non-light-emitting pixels;
an auxiliary electrode disposed below and electrically connected to the second anode of the non-light-emitting pixels;
a bank that covers edges of first anode and edges of the second anode, and that has first openings between the covered edges of the first anode and second openings between the covered edges of the second anode;
a cathode disposed above the first anode and the second anode, and electrically connected to the second anode;
first color filters corresponding to the first openings in the bank above the first anode of the light-emitting sub pixels; and
second color filters corresponding to the second openings in the bank above the second anode of the non-light-emitting pixels.
